(19) United States
(12) Patent Application Publication
(10) Pub. No.: US 2007/0216799 A1
(43) Pub. Date: Sep. 20, 2007

(54) CAMERA MODULE

(75) Inventor: Toshihiko Honma, Yamagata (JP)

Correspondence Address: MARGER JOHNSON & MCCOLLOM, P.C., 210 SW MORRISON STREET, SUITE 400, PORTLAND, OR, 97204, US

(73) Assignee: MITSUMI ELECTRIC CO. LTD., Tokyo (JP)

(21) Appl. No.: 11/683,956

(22) Filed: Mar. 8, 2007

(30) Foreign Application Priority Data
Mar. 16, 2006 (JP) 2006-072707

(51) Int. Cl. H04N 5/225; H01L 27/00

(52) U.S. Cl. 348/374; 250/208.1; 348/340

(57) ABSTRACT

A camera module having a macro switching function which can be switched between a normal photographing and a macro photographing is provided. The camera module includes a housing; a lens unit having at least one leans; a lens holder which houses the lens unit therein and is displaceable between a first position and a second position along an optical axis direction of the lens unit; a first magnetic member provided on the holder at the side of the first position; a second magnetic member provided on the holder at the side of the second position; a coil wound around the holder and provided in a close vicinity of the first magnetic member; a yoke which constitutes a part of or an entire of the housing, the yoke having a first portion provided at a position that faces the first magnetic member and a second portion provided at a position that faces the second magnetic member; a magnet provided on the yoke in a state that a space is left between the coil and the magnet; and an image pick-up device provided below the lens unit.

### BACKGROUND OF THE INVENTION

1. Field of the Invention

The present invention relates to a camera module, and more specifically to a camera module having a macro switching function which is used in relatively small-sized electronic apparatuses such as digital cameras, camera-equipped cellular phones and the like.

2. Description of the Prior Art

A camera module having a macro switching function is used in small-sized digital cameras, camera-equipped cellular phones and the like. The macro switching function is a function of the camera module that makes it possible to switch a photographing mode of the camera module between a normal photographing mode and a macro photographing mode. In more detail, such a camera module includes a hand-manipulated lever, and a holder having at least one lens which constitutes an optical system of the camera module. The camera module is configured so that the holder can be mechanically displaced in a direction of an optical axis of the lens between a position that is close to an image pick-up device and a position that is far away from the image pick-up device by manipulating the hand-manipulated lever. The former position of the lens holder corresponds to the normal photographing mode and the latter position of the lens holder corresponds to the macro photographing mode.

As described above, the conventional camera module having a macro switching function requires a hand-manipulated lever for carrying out the macro switching function. Therefore, the conventional camera module involves a problem in that when an excessive force is applied to the lever, there is a case that the lever is damaged.

### SUMMARY OF THE INVENTION

The present invention has been made in view of the problem described above, and therefore it is an object of the present invention is to provide a camera module having a macro switching function which can be switched between a normal photographing mode and a macro photographing mode without using a hand-manipulated lever as described above.

In order to achieve the object, the present invention is directed to a camera module, comprising: a housing; a lens unit having at least one leans which constitutes an optical system of the camera module; a lens holder which houses the lens unit therein, the lens holder being displaceable between a first position and a second position along an optical axis direction of the lens unit; a first magnetic member provided on the holder at the side of the first position; a second magnetic member provided on the holder at the side of the second position; a coil wound around the holder so that it is positioned in the close vicinity of the first magnetic member rather than the second magnetic member; a yoke which constitutes a part of or an entire of the housing, the yoke having a first portion provided at a position that faces the first magnetic member and a second portion provided at a position that faces the second magnetic member; a magnet provided on an inner circumferential surface of the yoke so that a space is left between the coil and the magnet; and an image pick-up device provided below the lens unit with a space therebetween

According to the camera module described above, the coil is arranged on the holder so that its lower end is positioned in the vicinity of the first magnetic member rather than the second magnetic member. Therefore, by controlling the magnetized polarity of the first magnetic member due to electromagnetic induction of the coil, it is possible to displace the holder from the first position to the second position, and vice versa. Further, even after the supply of the direct current has been stopped, it is possible to hold or maintain the holder at either of the first position or second position by virtue of the attraction force between the first portion of the yoke and the first magnetic member or the attraction force between the second portion of the yoke and the second magnetic member. Therefore, it is possible to displace the holder between the first position and the second position without provision of a hand-manipulated lever used in the conventional camera modules described above. Further, since it is not necessary to supply an electrical current to the coil after the holder has been displaced to either of the first position or second position, electrical power saving can be accomplished.

Further, in the camera module according to the present invention, it is preferred that the holder is adapted to be displaced from the first position to the second position along the optical axis direction of the lens unit by supplying a direct current flowing in one direction to the coil to generate a magnetic field in the coil so that the first magnetic member is repelled with the magnetic field generated by the first portion of the yoke; the holder is adapted to be held at the second position due to the second magnetic member being magnetically attracted to the second portion of the yoke by stopping the supply of the current to the coil; the holder is adapted to be displaced from the second position to the first position along the optical axis direction of the lens unit by supplying a reverse direct current to the coil to generate a magnetic field in the coil so that the first magnetic member is attracted to the magnetic field generated by the first portion of the yoke; and the holder is adapted to be held at the first position due to the first magnetic member being magnetically attracted to the first portion of the yoke by stopping the supply of the direct current to the coil

In this camera module, it is also preferred that the first position is a position where the holder is displaced close to the image pick-up device to provide a normal photographing mode, and the second position is a position where the holder is displaced far away from the image pick-up device to provide a macro photographing mode.

In this way, a macro switching function is carried out in the camera module of the present invention. That is, the camera module of the present invention can be switched between the normal photographing mode and the macro photographing mode without provision of a hand-manipulated lever used in the conventional camera modules described above.

Further, in the camera module according to the present invention, it is also preferred that the holder is a roughly cylindrical member made of a synthetic resin and an outer peripheral wall of the holder has an annular rib portion integrally formed on the upper portion thereof and a coil holding portion having a diameter smaller than that of the annular rib portion and extending below the annular rib portion, and the coil is a cylindrical coil having a lower end and an upper end, wherein the coil is provided on the coil holding portion of the holder so that the lower end of the coil is in contact with the first magnetic member while the upper end of the coil is in contact with the lower surface of the annular rib portion so that it does not contact the second magnetic member directly.

With this structure, it is possible to reduce the attraction force or repelling force exerted between the second magnetic member and the second portion of the yoke to such an extent that it does not interfere with the displacement of the holder. Further, by adjusting the thickness of the annular rib portion, it is possible to control smooth displacement of the holder.

Furthermore, in the camera module according to the present invention, it is also preferred that the first magnetic member, the second magnetic member, the first portion of the yoke, and the second portion of the yoke have ring-like shapes and are made of iron, respectively.

With this structure, since uniform and sufficient attraction force can be obtained between the first portion of the yoke and the first magnetic member or the attraction force between the second portion of the yoke and the second magnetic member, it is possible to hold the holder at either of the first or second position reliably.

The above and other objects, features and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1 is a cross-sectional view of a camera module 1 according to an embodiment of the present invention, which shows a state that a holder 4 is held at a first position to provide a normal photographing mode;

FIG. 2 is another cross-sectional view of the camera module 1, which shows a state that a direct current is supplied to a coil 5 of the camera module 1 and the holder 4 is displaced from the first position to a second position;

FIG. 3 is a still another cross-sectional view of the camera module 1, which shows a state that the holder 4 of the camera module 1 is held at the second position to provide a macro photographing mode; and

FIG. 4 is a yet another cross-sectional view of the camera module 1, which shows a state that a reverse direct current is supplied to the coil 5 of the camera module 1 and the holder 4 is displaced from the second position to the first position.

### DETAILED DESCRIPTION OF THE INVENTION

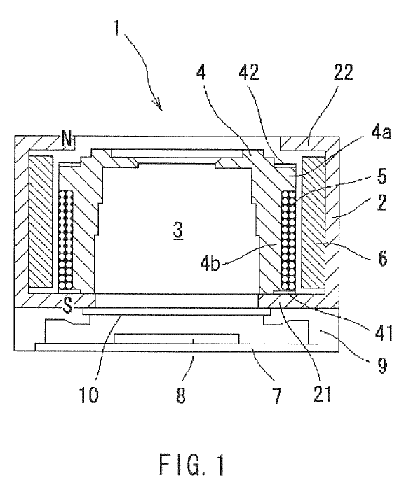

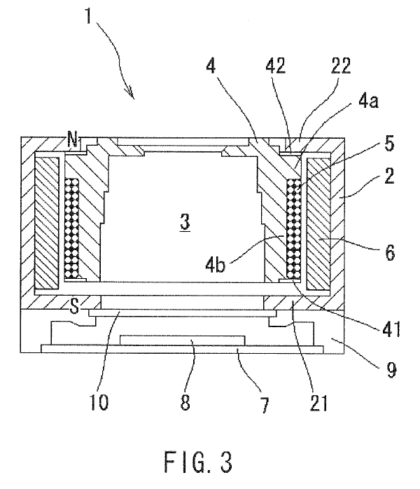

A camera module according to an embodiment of the present invention will be described below with reference to FIGS. 1 to 4. FIGS. 1 to 4 are cross sectional views of the camera module 1 of the embodiment according to the present invention, wherein FIG. 1 is shows a camera module 1 in a normal photographing mode and FIG. 3 shows a camera module 1 in a macro photographing mode. In this regard, it is to be noted that in this specification the terms “upper” or “top” and “lower” or “bottom” are used to denote the direction where a second portion 22 of a yoke 2 is located and the direction where a substrate 7 is located, respectively.

The camera module 1 is composed from a housing; a lens unit 3 having at least one lens which constitutes an optical system of the camera module 1; a holder 4 which houses the lens unit 3 and is displaceable between a first position and a second position along an optical axis direction of the lens unit 3; a first magnetic member 41 provided on the holder 4 at the side of the first position; a second magnetic member 42 provided on the holder 4 at the side of the second position; a coil 5 wound around the holder 4 and provided in the vicinity of the first magnetic member 41 rather than the second magnetic member 42; a yoke 2 which constitutes a part of or an entire of the housing, the yoke 2 having a first portion provided at a position that faces the first magnetic member 41 and a second portion provided at a position that faces the second magnetic member 42; a magnet 6 provided on the yoke 2 so that a space is left between the coil 5 and the magnet 6; and an image pick-up device 8 provided an image pick-up device provided below the lens unit 3 with a space therebetween.

In the camera module having the above structure, the holder 4 is adapted to be displaced from the first position to the second position along the optical axis direction of the lens unit 3 by supplying a direct current in one direction to the coil 5 to generate a magnetic field in the coil 5 so that the first magnetic member 41 is repelled with the magnetic field generated by the first portion 21 of the yoke 2; the holder 4 is adapted to be held at the second position 22 due to the second magnetic member 42 being magnetically attracted to the second portion 22 of the yoke 2 by stopping the supply of the direct current to the coil 5; the holder 4 is adapted to be displaced from the second position to the first position along the optical axis direction of the lens unit 3 by supplying a reverse direct current to the coil 5 to generate a magnetic field in the coil 5 so that the first magnetic member 41 is attracted to the magnetic field generated by the first portion 21 of the yoke 2; and the holder 4 is adapted to be held at the first position due to the first magnetic member 41 being magnetically attracted to the first portion 21 of the yoke 2 by stopping the supply of the reverse direct current to the coil 5.

Hereinbelow, a detailed description will be made with regard to the respective components.

As shown in FIG. 1, the housing of the camera module 1 is constituted from the yoke 2 which is a substantially cylindrical member made of iron. In other words, in this embodiment, the yoke 2 also functions as the housing of the camera module 1. Specifically, the yoke 2 has a ring-shaped first portion 21 at the side of the image pick-up device 8, a ring-shaped second portion 22 at the opposite side, and a cylindrical wall portion coupled between the outer peripheral portions of the first portion 21 and the second portion 22. As will be described later, the first portion 21 is located at a position that faces the first magnetic member 41 on the holder 4 and the second portion 22 is located at a position that faces the second magnetic member 42 one the holder 4. In this regard, it is to be noted that the housing may be formed from a separate member from the yoke 2, or the yoke 2 may be formed using a part of the housing.

The holder 4 is a roughly cylindrical member made of a synthetic resin. The outer peripheral wall of the holder 4 has an annular rib portion 4a integrally formed on the upper portion thereof and a coil holding portion 4b having a smaller diameter than the diameter of the annular rib portion 4a and extending below the annular rib portion 4a. Further, the holder 4 has a hollow space inside thereof. Inside the hollow space, the lens unit 3 which constitutes the optical system of the camera module 1 is provided (Note that the lens unit 3 is omitted from the drawings, but the hollow space to which the lens unit 3 is to be provided is indicated with the reference numeral 3 in the drawings).

Around the coil holding portion 4b of the holder 4, the coil 5 is wound. Further, the first magnetic member 41 which is a ring-shaped iron member is disposed on the lower end portion of the holder 4 (on the side of the image pick-up device 8). Furthermore, the second magnetic member 42 which is also a ring-shaped iron member is disposed on the upper end portion of the holder 4, that is, on the annular rib portion 4a of the holder 4 (on the opposite side of the image pick-up device 8).

As shown in FIG. 1, when the camera module 1 is in a normal photographing mode, the holder 4 is shifted to the side of the image pick-up device 8, and in this state the first magnetic member 41 is magnetically attracted to the first portion 21 of the yoke 2 and held at the position. The position of the holder 4 in this normal photographing mode is referred to as the first position. Further, as shown in FIG. 3, when the camera module 1 is in a macro photographing mode, the holder 4 is shifted to the opposite side of the image pick-up device 8, and in this state the second magnetic member 42 is magnetically attracted to the second portion 22 of the yoke 2 and held at the position. The position of the holder 4 in this macro photographing mode is referred to as the second position.

The coil 5 is formed from a coil obtained by winding a wire into a cylindrical shape. The coil 5 is provided around the coil holding portion 4b of the holder 4 so that the coil 5 is positioned in the vicinity of the first magnetic member 41 rather than the second magnetic member 42. In more details, the coil 5 is provided on the coil holding portion 4b so that the lower end of the coil 5 is in contact with the first magnetic member 41 while the upper end of the coil 5 is in contact with the lower surface of the annular rib portion 4a so that it does not contact the second magnetic member 42 directly. Namely, there is a gap between the upper end of the coil 5 and the second magnetic member 42 and this gap corresponds to the thickness of the annular rib portion 4a. In this regard, it is to be noted that the lower end of the coil 5 is not necessarily in contact with the first magnetic member 41.

The magnet 6 is formed from a cylindrical permanent magnet arranged on the inner circumferential surface of the cylindrical wall portion of the yoke 2, and it is magnetized so that the lower end is S pole and the upper end is N pole.

Accordingly, the first portion 21 of the yoke 2 is also magnetized to S pole and the second portion 22 of the yoke 2 is also magnetized to N pole. Further, the magnet 6 is arranged around the coil 5 so that a space is left therebetween.

The image pick-up device 8 is a CCD or COMS sensor, and it is mounted on the substrate 10 at a position below the lens unit 3. Note that in the drawings, the reference numeral 9 denotes a base member and the reference numeral 10 is an IR cut filter.

Hereinbelow, an operation of the camera module 1 of this embodiment will be described in detail with reference to FIGS. 1 to 4.

FIG. 1 shows the camera module 1 in the normal photographing mode. In this normal photographing mode, the holder 4 is in the first position at which the first magnetic member 41 is magnetically attracted to the first portion 21 of the yoke 2 and held at the position. Therefore, the lens unit 3 provided inside the holder 4 is also sifted to the side close to the image pick-up device 8. In this state, no direct current is supplied to the coil 5.

Next, a description will be made with regard to a process for switching the camera module 1 from the normal photographing mode to the macro photographing mode.

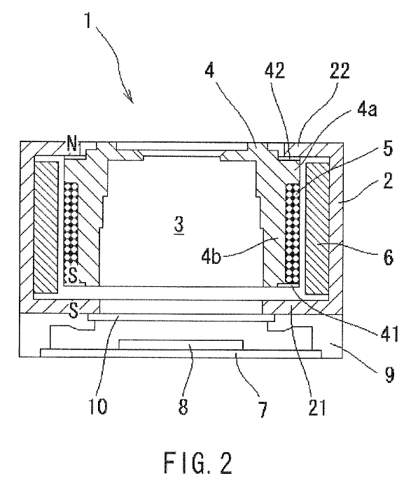

In a state that the camera module 1 is in the normal photographing mode shown in FIG. 1, when a direct current is supplied to the coil 5 so as to flow in one direction, the lower end of the coil 5 is magnetized into S pole due to electromagnetic induction. In other word, the directed current is supplied to the coil 5 in a direction that the lower end of the coil 5 is magnetized into S pole. Therefore, the first magnetic member 41 which is in contact with the lower end of the coil 5 is also magnetized into S pole, so that the first magnetic member 41 is repelled with the first portion 21 of the yoke 2 which is magnetized into S pole. Due to this repellant force, the holder 4 is displaced from the first position to the second position along the optical axis direction as shown in FIG. 2. In this state, the second magnetic member 42 is magnetized into N pole which is the same pole as the second portion 22 of the yoke 2. However, since the coil 5 is arranged below the annular rib 4a so as to be spaced apart from the second magnetic member 42 to the extent of the gap corresponding to the thickness of the annular rib portion 4a, the degree of the magnetization of the second magnetic member 42 is negligible small. Therefore, the repellant force between the first portion 21 of the yoke 2 and the first magnetic member 41 can overcome the repellant force between the second portion 22 of the yoke 2 and the second magnetic member 42, so that the holder 4 can be displaced from the first position to the second position.

When the holder 4 is displaced from the first position to the second position and the second magnetic member 42 is in contact with the second portion 22 of the yoke 2, the displacement of the holder 4 is completed. When the displacement of the holder 4 is completed, the supply of the direct current to the coil 5 is stopped. In this state, since the second magnetic member 42 is in contact with the second portion 22 of the yoke 2, the second magnetic member 42 is magnetically attracted to the second portion 22 and kept to be held at the position even after the supply of the direct current has been stopped. This state is the macro photographing mode, and it is shown in FIG. 3.

Next, a description will be made with regard to a process for switching the camera module 1 form the macro photographing mode to the normal photographing mode.

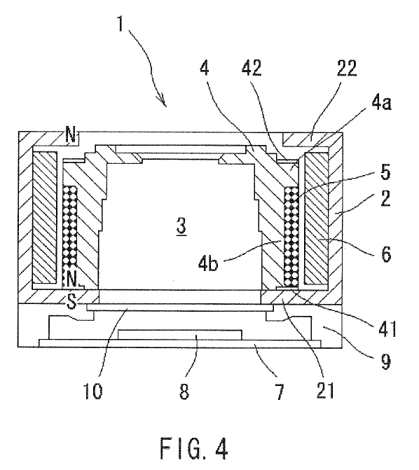

In a state that the camera module 1 is in the macro photographing mode shown in FIG. 3, when a reverse direct current is supplied to the coil 5, the lower end portion of the coil 5 is magnetized into N pole due to electromagnetic induction. Therefore, the first magnetic member 41 which is in contact with the lower end of the coil 5 is also magnetized into N pole, so that the first magnetic member 41 is attracted to the first portion 21 of the yoke 2 magnetized to S pole. In this state, the second magnetic member 42 is magnetized to S pole. However, since the coil 5 is arranged below the annular rib portion 4a so as to be spaced apart from the second magnetic member 42 as described above, the degree of the attraction force between the second magnetic member 42 and the second portion 22 of the yoke 2 is not so strong. Therefore, the attraction force between the first portion 21 of the yoke 2 and the first magnetic member 41 can overcome the attraction force between the second portion 22 of the yoke 2 and the second magnetic member 42, so that the holder 4 can be displaced from the second position to the first position as shown in FIG. 4.

When the holder 4 is displaced from the second position to the first position and the first magnetic member 41 is in contact with the first portion 21 of the yoke 2, the displacement of the holder 4 is completed. When the displacement of the holder 4 is completed, the supply of the direct current to the coil 5 is stopped. In this state, the first magnetic member 41 is in contact with the first portion 21 of the yoke 2, the first magnetic member 41 is magnetically attracted to the first portion 21 and kept to be held at the position even after the supply of the direct current has been stopped. This state is shown in FIG. 1.

According to the camera module 1 of this embodiment described above, the coil 5 is arranged on the holder 4 so that its lower end is positioned in the vicinity of the first magnetic member 41 rather than the second magnetic member 42. Therefore, by controlling the magnetized polarity of the first magnetic member 41 due to electromagnetic induction of the coil 5, it is possible to displace the holder 4 from the first position to the second position, and vice versa. Further, even after the supply of the direct current has been stopped, it is possible to hold or maintain the holder 4 at either of the first position or second position by virtue of the attraction force between the first portion 21 of the yoke 2 and the first magnetic member 41 or the attraction force between the second portion 22 of the yoke 2 and the second magnetic member 42. Therefore, it is possible to displace the holder 4 between the first position and the second position without provision of a hand-manipulated lever used in the conventional camera modules described above. That is, the camera module 1 can be switched between the normal photographing mode and the macro photographing mode without provision of a hand-manipulated lever used in the conventional camera modules described above. Further, since it is not necessary to supply an electrical current to the coil 5 after the holder 4 has been displaced to either of the first position or second position, electrical power saving can be accomplished.

Further, in the camera module 1 described above, the first magnetic member 41, the second magnetic member 42, the first portion 21 of the yoke 2, and the second portion 22 of the yoke 2 have ring-like shapes and are made of iron. Therefore, since uniform and sufficient attraction force can be obtained between the first portion 21 of the yoke 2 and the first magnetic member 41 or the attraction force between the second portion 22 of the yoke 2 and the second magnetic member 42, it is possible to hold the holder 4 at either of the first or second position reliably.

In the foregoing, the present invention has been described based on the embodiment shown in the drawing. However, the present invention is not limited to the embodiment.

For example, the camera module 1 may be provided with any guide means for guiding the up and down displacement of the holder 4 along the optical axis direction.

Further, the polarities of the first portion 21 and the second portion 22 of the yoke 2 may be reversed. In this case, the direction of the electrical current flowing through the coil 5 is also reversed.

Furthermore, the thickness of the annular rib portion 4a should be appropriately set so that smooth displacement of the holder 4 can be ensured.

Further, although the embodiment described above is directed to the camera module having the macro switching function which can be switched between the normal photographing condition and the macro photographing condition, the present invention can also be applied to a camera module having a switching function between a normal photographing condition and a zoom up photographing condition.

Finally, it should be understood that the present invention is not limited to the preferred embodiments described hereinabove and, needless to say, a variety of modifications or variations may be made without departing from the scope of the invention defined in the following claims.

Further, it is also to be understood that the present disclosure relates to subject matter contained in Japanese Patent Application No. 2006-072707 (filed on Mar. 16, 2006) which is expressly incorporated herein by reference in its entirety.

What is claimed is:

1. A camera module, comprising:
a housing;
a lens unit having at least one leans which constitutes an optical system of the camera module;
a lens holder which houses the lens unit therein, the lens holder being displaceable between a first position and a second position along an optical axis direction of the lens unit;
a first magnetic member provided on the holder at the side of the first position;
a second magnetic member provided on the holder at the side of the second position;
a coil wound around the holder so that it is positioned in the close vicinity of the first magnetic member rather than the second magnetic member;
a yoke which constitutes a part of or an entire of the housing, the yoke having a first portion provided at a position that faces the first magnetic member and a second portion provided at a position that faces the second magnetic member;
a magnet provided on an inner circumferential surface of the yoke so that a space is left between the coil and the magnet; and
an image pick-up device provided below the lens unit with a space therebetween.

2. The camera module as claimed in claim 1, wherein the holder is adapted to be displaced from the first position to the second position along the optical axis direction of the lens unit by supplying a direct current flowing in one direction to the coil to generate a magnetic field in the coil so that the first magnetic member is repelled with the magnetic field generated by the first portion of the yoke; the holder is adapted to be held at the second position due to the second magnetic member being magnetically attracted to the second portion of the yoke by stopping the supply of the current to the coil; the holder is adapted to be displaced from the second position to the first position along the optical axis direction of the lens unit by supplying a reverse direct current to the coil to generate a magnetic field in the coil so that the first magnetic member is attracted to the magnetic field generated by the first portion of the yoke; and the holder is adapted to be held at the first position due to the first magnetic member being magnetically attracted to the first portion of the yoke by stopping the supply of the direct current to the coil.

3. The camera module as claimed in claim 1, wherein the first position is a position where the holder is displaced close to the image pick-up device to provide a normal photographing mode, and the second position is a position where the holder is displaced far away from the image pick-up device to provide a macro photographing mode.

4. The camera module as claimed in claim 1, wherein the holder is a roughly cylindrical member made of a synthetic resin and an outer peripheral wall of the holder has an annular rib portion integrally formed on the upper portion thereof and a coil holding portion having a diameter smaller than that of the annular rib portion and extending below the annular rib portion, and the coil is a cylindrical coil having a lower end and an upper end, wherein the coil is provided on the coil holding portion of the holder so that the lower end of the coil is in contact with the first magnetic member while the upper end of the coil is in contact with the lower surface of the annular rib portion so that it does not contact the second magnetic member directly.

5. The camera module as claimed in claim 1, wherein the first magnetic member, the second magnetic member, the first portion of the yoke, and the second portion of the yoke have ring-like shapes and are made of iron, respectively.
